(19) United States
(12) Patent Application Publication
(10) Pub. No.: US 2026/0328846 A1
(43) Pub. Date: Oct. 22, 2026

(54) METHOD AND APPARATUS FOR EVALUATING HEALTH STATE OF MARINE ALTERNATING CURRENT MOTOR, AND DEVICE

(71) Applicant: GUANGDONG OCEAN UNIVERSITY, Zhanjiang (CN)

(72) Inventors: Zhiqiang LIAO, Zhanjiang (CN); Xuewei SONG, Zhanjiang (CN); Baozhu JIA, Zhanjiang (CN); Zhengning ZHONG, Zhanjiang (CN); Weizhen HAO, Zhanjiang (CN); Jinhai GAN, Zhanjiang (CN); Jie HOU, Zhanjiang (CN)

(21) Appl. No.: 19/707,091

(22) Filed: Jun. 12, 2026

Related U.S. Application Data
(63) Continuation of application No. PCT/CN2024/124978, filed on Oct. 15, 2024.

(30) Foreign Application Priority Data
Dec. 15, 2023 (CN) 202311738203.6

(51) Int. Cl. G01R 31/34; G01R 19/00; G01R 31/00; G01R 31/42; G06F 17/16

(52) U.S. Cl. CPC G01R 31/343; G01R 19/0053; G01R 31/008; G01R 31/42; G06F 17/16

(57) ABSTRACT

A method and apparatus for evaluating the health state of a marine alternating current motor, and a device. The method comprises: using Clarke transformation to transform multiple fault-free three-phase current signals of a normal alternating current motor into a standard stator current circular signal scatter diagram, and to transform multiple three-phase current signals under test of an alternating current motor under test into a stator current circular signal scatter diagram under test; dividing scatter diagrams to obtain multiple first scatter regions and multiple second scatter regions; determining health evaluation parameters base on first coordinates of each signal point in each first scatter region and second coordinates of each signal point in each second scatter region; and based on the health evaluation parameters, determining a health score of the alternating current motor under test, so as to evaluate the health state of the alternating current motor under test.

### CROSS-REFERENCE TO RELATED APPLICATION

This disclosure is a National Stage of International Application No. PCT/CN2024124978, filed on Oct. 15, 2024, which claims priority to Chinese Patent Application No. 202311738203.6, entitled “METHOD AND APPARATUS FOR EVALUATING HEALTH STATE OF MARINE ALTERNATING CURRENT MOTOR, AND DEVICE”, filed with the China National Intellectual Property Administration (CNIPA) on Dec. 15, 2023, the entire contents of the mentioned applications are incorporated herein by reference.

### TECHNICAL FIELD

The present disclosure relates to the technical field of ship motor state monitoring, and in particular, to a method, an apparatus, and a device for evaluating health state of a marine alternating current motor.

### BACKGROUND

As the main power and traction equipment in various industrial production activities, the working state of an electric motor directly affects production accuracy and efficiency. The motor system is an important component of rotating machinery. Accurate motor fault diagnosis is of great significance for ensuring the safe operation of rotating machinery.

In mechanical fault diagnosis, temperature-based diagnosis and vibration-based diagnosis are currently commonly used methods. Temperature-based diagnosis directly measures changes in temperature signals caused by faults by bringing a temperature sensor into contact with the mechanical equipment. However, this method is often insufficiently sensitive to incipient minor faults, resulting in low accuracy for fault diagnosis. Vibration-based diagnosis is a relatively direct fault diagnosis method originally which can provide more fault information. However, due to limitations in the motor's operating environment and working conditions, the collected vibration signals are not purely fault signals; they are also affected by external environmental influences and vibrations from other components during operation. Therefore, the signals extracted by the vibration detection method are greatly affected by other interference signals. Thus, for motor fault diagnosis, the diagnostic effectiveness of the vibration detection method is not ideal, and its applicability is limited.

Therefore, the accuracy of the existing technologies for evaluating the health state of the alternating current motor cannot be guaranteed.

### SUMMARY

In response to the problems existing in the prior art, embodiments of the present disclosure provide a method, an apparatus, and a device for evaluating health state of a marine alternating current motor, aiming to solve or partially solve the technical problem in the prior art of being unable to accurately determine the fault state of the marine alternating current motor, thereby making it impossible to accurately evaluate the health state of the motor.

In a first aspect, the present disclosure provides a method for evaluating the health state of a marine alternating current motor, the method includes:
obtaining a plurality of fault-free three-phase current signals of a normal alternating current motor, and using Clarke transformation to transform the plurality of fault-free three-phase current signals into a standard stator current circular signal scatter diagram;
obtaining a plurality of three-phase current signals under test of an alternating current motor under test, and transforming the plurality of three-phase current signals under test into an initial stator current circular signal scatter diagram under test;
determining angles between each signal point in the initial stator current circular signal scatter diagram under test and a preset direction vector, and sorting the signal points on the basis of the angles to obtain a target stator current circular signal scatter diagram under test;
performing region division on the target stator current circular signal scatter diagram under test on a basis of a preset angle threshold to obtain a plurality of first scatter regions, and dividing a preprocessed standard stator current circular signal scatter diagram on the basis of the angle threshold to obtain a plurality of second scatter regions;
determining health evaluation parameters on a basis of first coordinates of each signal point in each first scatter region and second coordinates of each signal point in each second scatter region; and
determining a health score of the alternating current motor under test on the basis of the health evaluation parameters, and evaluating the health state of the alternating current motor under test on the basis of the health score.

In the above solution, determining the angles between each signal point in the initial stator current circular signal scatter diagram under test and the preset direction vector includes:
determining the modulus of the current vector on the basis of the coordinates of the current signal points and the coordinate of the origin in the initial stator current circular signal scatter diagram under test for any current vector formed by a current signal point and the origin in the initial stator current circular signal scatter diagram under test;
determining the modulus of the preset direction vector;
determining the dot product between the preset direction vector and the current vector; and
determining the angle between the current vector and the preset direction vector on the basis of the modulus of the current vector, the modulus of the preset direction vector, and the dot product between the preset direction vector and the current vector.

In the above solution, when the health evaluation parameters include a center of gravity offset and a radius standard deviation, determining the health evaluation parameters on the basis of first coordinates of each signal point in each first scatter region and second coordinates of each signal point in each second scatter region includes:
determining a first center of gravity offset for each first scatter region and a first radius for each signal point in each first scatter region based on the first coordinates of each signal point in each first scatter region; determining the mean of the first center of gravity offsets as the current center of gravity offset of the target stator current circular signal scatter diagram under test;
determining a second center of gravity offset for each second scatter region and a second radius for each signal point in each second scatter region based on the second coordinates of each signal point in each second scatter region; determining the mean of the second center of gravity offsets as the reference center of gravity offset;
determining first radius standard deviations for each first scatter region based on the first radius for each signal point in each first scatter region; determining the mean of the first radius standard deviations as the current radius standard deviation of the target stator current circular signal scatter diagram under test; and
determining a second radius standard deviation for each second scatter region based on the second radius for each signal point in each second scatter region; determining the mean of the second radius standard deviations as the reference radius standard deviation of the preprocessed standard stator current circular signal scatter diagram.

In the above solution, when the health evaluation parameters include a kurtosis value, a skewness value, and a root mean square value, determining the health evaluation parameters on the basis of first coordinates of each signal point in each first scatter region and second coordinates of each signal point in each second scatter region includes:
determining the first radii of all signal points in each first scatter region, and identifying the minimum first radius from the first radii of all the signal points;
obtaining a distance difference between the first radius of each remaining signal point in each first scatter region and the minimum first radius; the remaining signal points in the first scatter region are all signal points in the first scatter region except for the signal point corresponding to the minimum first radius;
determining the kurtosis value of the distance difference, the skewness value of the distance difference, and the root mean square value of the distance difference in each first scatter region based on all the distance differences in each first scatter region;
determining the second radii of all signal points in each second scatter region, and identifying the minimum second radius from the second radii of all the signal points;
obtaining a distance differences between the second radii of each remaining signal point in each second scatter region and the minimum second radius; the remaining signal points in the second scatter region are all signal points in the second scatter region except for the signal point corresponding to the minimum second radius; and
determining the kurtosis value of the distance difference, the skewness value of the distance difference, and the root mean square value of the distance difference in each second scatter region based on all the distance differences in each second scatter region.

In the above solution, determining the health score of the alternating current motor under test on the basis of the health evaluation parameters includes:
determining a reference evaluation value η for the preprocessed standard stator current circular signal scatter diagram according to the formula η=\sqrt{(R_{U}−0.6R_{T})²};
determining a current evaluation value η′ for the target stator current circular signal scatter diagram under test according to the formula

$${η}^{′} = \sqrt{{( {R}_{U}^{′} - 0.6 {R}_{T}^{′} )}^{2}} ;$$

and
determining the health score ζ for the alternating current motor under test according to the formula

$$ς = 100 - \frac{\vert {η}^{′} - η \vert}{γ} ;$$

where:
R_{U} is the reference radius standard deviation, R_{T} is the reference center of gravity offset,

$${R}_{U}^{′}$$

is the current radius standard deviation,

$${R}_{T}^{′}$$

is the current center of gravity offset, γ is a reference score corresponding to the preprocessed standard stator current circular signal scatter diagram.

In the above solution, determining a health score of the alternating current motor under test on the basis of the health evaluation parameters includes:
constructing a parameter matrix under test based on the kurtosis value of the distance difference, the skewness value of the distance difference, and the root mean square value of the distance difference in each first scatter region;
constructing a reference parameter matrix based on the kurtosis value of the distance difference, the skewness value of the distance difference, and the root mean square value of the distance difference in each second scatter region;
determining a similarity coefficient between the parameter matrix under test and the reference parameter matrix; and
determining the health score S of the alternating current motor under test based on the formula

$$S = \frac{{η}^{″} - 0.7}{( 1 - 0.7 ) ⋆ 0.01} ,$$

where η″ is the similarity coefficient.

In the above solution, determining the similarity coefficient between the parameter matrix under test and the reference parameter matrix includes:
determining a covariance between the parameter matrix under test and the reference parameter matrix;
determining a first standard deviation of the parameter matrix under test and a second standard deviation of the reference parameter matrix;
determining a product value of the first standard deviation and the second standard deviation; and
determining the similarity coefficient between the parameter matrix under test and the reference parameter matrix according to the covariance and the product value of the first standard deviation and the second standard deviation; the similarity coefficient is the quotient between the covariance and the product value.

In the above solution, determining the kurtosis value of the distance difference, the skewness value of the distance difference, and the root mean square value of the distance difference in each first scatter region includes:
determining the kurtosis value χ of the distance difference in each first scatter region according to the formula

$$χ = \frac{1}{N} {{\sum }_{i = 1}}^{N} {d}_{i}^{4} ;$$

determining the skewness value γ of the distance difference in each first scatter region according to the formula

$$γ = \frac{1}{N} {{\sum }_{i = 1}}^{N} {d}_{i}^{3} ;$$

determining the root mean square value Xᵣₘₛ of the distance difference in each first scatter region according to the formula

$${X}_{rms} \sqrt{\frac{1}{N} {\sum }_{i = 1}^{N} {d}_{i}^{2}} ;$$

where

N is the number of distance differences in the first scatter region, i is the index of the distance difference in the first scatter region, dᵢ is the i-th distance difference.

In a second aspect, the present disclosure provides an apparatus for evaluating the health state of a marine alternating current motor, the apparatus includes a transformation unit, a first determination unit, and a second determination unit.

The transformation unit is configured to obtain a plurality of fault-free three-phase current signals of a normal alternating current motor, and transform the plurality of fault-free three-phase current signals into a standard stator current circular signal scatter diagram using Clarke transformation; obtain a plurality of three-phase current signals under test of an alternating current motor under test, and transform the plurality of three-phase current signals under test into an initial stator current circular signal scatter diagram under test.

The first determination unit is configured to determine angles between each signal point in the initial stator current circular signal scatter diagram under test and a preset direction vector, and sort the signal points on the basis of the angles to obtain a target stator current circular signal scatter diagram under test; perform region division on the target stator current circular signal scatter diagram under test on a basis of a preset angle threshold to obtain a plurality of first scatter regions, and divide a preprocessed standard stator current circular signal scatter diagram on the basis of the angle threshold to obtain a plurality of second scatter regions.

The second determination unit is configured to determine health evaluation parameters on a basis of first coordinates of each signal point in each first scatter region and second coordinates of each signal point in each second scatter region, determine a health score of the alternating current motor under test on the basis of the health evaluation parameters, and evaluate the health state of the alternating current motor under test on the basis of the health score.

In a third aspect, the present disclosure provides a computer device including a memory, a processor, and a computer program stored on the memory and executable on the processor, where the processor implements the steps of any of the methods described above when executing the program.

The present disclosure provides a method, an apparatus, and a device for evaluating health state of a marine alternating current motor. The method includes: obtaining a plurality of fault-free three-phase current signals of a normal alternating current motor, and using Clarke transformation to transform the plurality of fault-free three-phase current signals into a standard stator current circular signal scatter diagram; obtaining a plurality of three-phase current signals under test of an alternating current motor under test, and transforming the plurality of three-phase current signals under test into an initial stator current circular signal scatter diagram under test; determining angles between each signal point in the initial stator current circular signal scatter diagram under test and a preset direction vector, and sorting the signal points on the basis of the angles to obtain a target stator current circular signal scatter diagram under test; performing region division on the target stator current circular signal scatter diagram under test on a basis of a preset angle threshold to obtain a plurality of first scatter regions, and dividing a preprocessed standard stator current circular signal scatter diagram on the basis of the angle threshold to obtain a plurality of second scatter regions; determining health evaluation parameters on a basis of first coordinates of each signal point in each first scatter region and second coordinates of each signal point in each second scatter region; and determining a health score of the alternating current motor under test on the basis of the health evaluation parameters, and evaluating the health state of the alternating current motor under test on the basis of the health score. In this way, based on the collected stator currents, the Clarke transformation is used to transform the multiple fault-free three-phase current signals of the normal alternating current motor into a standard stator current circular signal scatter diagram, and to transform the multiple three-phase current signals under test of the alternating current motor under test into a stator current circular signal diagram under test; health evaluation parameters are determined according to the coordinates of each signal point in each scatter region, and the health score of the alternating current motor is quantified using the health evaluation parameters, thereby enabling accurate evaluation of the motor's health state based on the health score.

### BRIEF DESCRIPTION OF THE DRAWINGS

Through the detailed description of the preferred embodiments below, various other advantages and benefits will become apparent to those of ordinary skill in the art. The accompanying drawings are merely for the purpose of illustrating the preferred embodiments and are not to be construed as limiting the present disclosure. Throughout the drawings, the same reference numerals are used to denote the same components. In the drawings:

FIG. 1 illustrates a flowchart of a method for evaluating the health state of a marine alternating current motor according to one embodiment of the present disclosure;

FIG. 2 illustrates a waveform diagram of fault-free three-phase alternating current signals according to one embodiment of the present disclosure;

FIG. 3 illustrates a standard stator current circular signal diagram corresponding to the fault-free three-phase alternating current signals according to one embodiment of the present disclosure;

FIG. 4 to FIG. 10 illustrate stator current circular signal diagrams under test corresponding to an alternating current motor experiencing different types of faults according to one embodiment of the present disclosure;

FIG. 11 illustrates a schematic diagram of an angle between a current vector and a direction vector in an initial stator current circular signal scatter diagram under test according to one embodiment of the present disclosure; and

FIG. 12 illustrates a schematic diagram of the structure of a device for evaluating the health state of a marine alternating current motor according to one embodiment of the present disclosure.

### DETAILED DESCRIPTION OF THE EMBODIMENTS

The exemplary embodiments of the present disclosure will be described in more detail below with reference to the accompanying drawings. Although the exemplary embodiments of the present disclosure are shown in the accompanying drawings, it should be understood that the present disclosure may be implemented in various forms and should not be limited by the embodiments described herein. On the contrary, these embodiments are provided to enable a more thorough understanding of this disclosure and to fully convey the scope of the present disclosure to those skilled in the art.

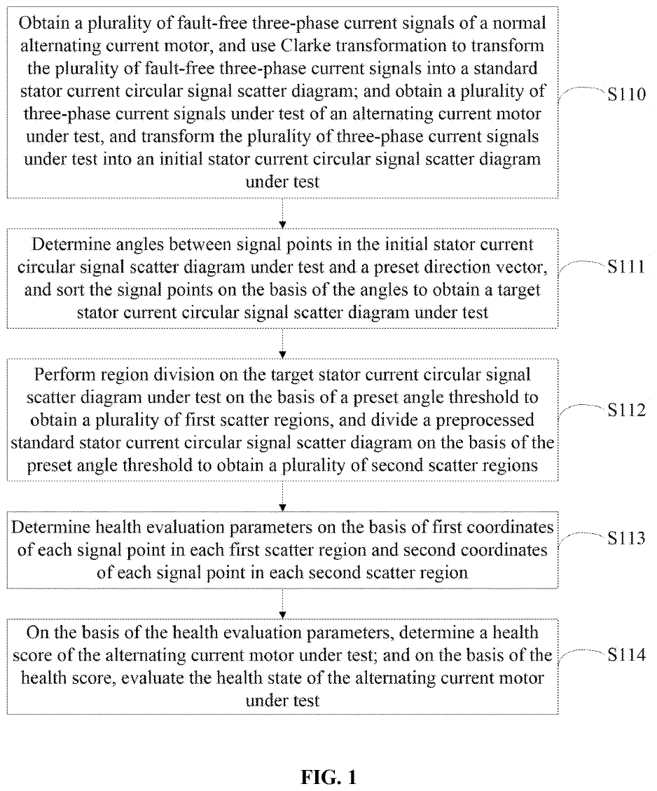

The present disclosure provides a method for evaluating the health state of the alternating current motor. As shown in FIG. 1, the method includes the following steps.

S110: obtain a plurality of fault-free three-phase current signals of a normal alternating current motor, and use Clarke transformation to transform the plurality of fault-free three-phase current signals into a standard stator current circular signal scatter diagram; and obtain a plurality of three-phase current signals under test of an alternating current motor under test, and transform the plurality of three-phase current signals under test into an initial stator current circular signal scatter diagram under test.

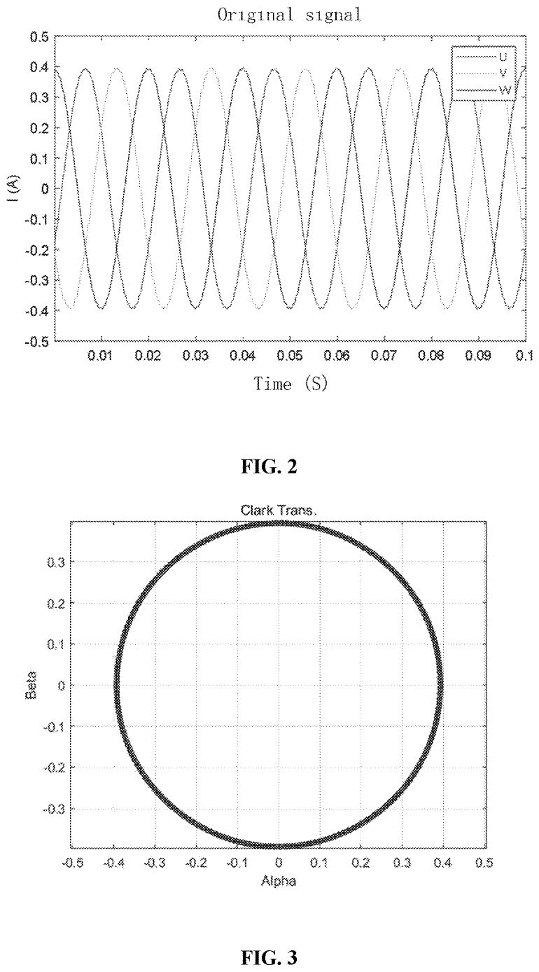

In the embodiments of the present disclosure, signals from a fault-free alternating current motor are collected using current transformers based on a preset sampling frequency to obtain
a plurality of the fault-free three-phase current signals (U, V, W) of the alternating current motor, or a plurality of fault-free three-phase current signals may be obtained through simulation experiments, without limitation. A waveform diagram of the three-phase current signals is shown in FIG. 2.

Clarke transformation is used to transform the plurality of fault-free three-phase current signals into a standard stator current circular signal scatter diagram. Clarke transformation is a mathematical transformation method that transforms three-phase voltages or currents into components on two orthogonal axes. The purpose is to transform the complex changes of three-phase voltages or currents into simple changes on two orthogonal axes for more accurate analysis and calculation, thereby improving the stability and efficiency of subsequent data processing.

In one embodiment, the plurality of fault-free three-phase current signals are transformed into a standard stator current circular signal scatter diagram includes:

For any fault-free three-phase current signal, the three-phase current signal is transformed into a d-axis component I_{d} on an orthogonal axis according to the formula

$${I}_{d} = \frac{2}{3} ( {I}_{a} - \frac{1}{2} {I}_{b} - \frac{1}{2} {I}_{c} ) .$$

The three-phase current signal is transformed into a q-axis component I_{q} on the orthogonal axis according to the formula

$${I}_{q} = \frac{2}{3} ( \frac{\sqrt{3}}{2} {I}_{b} - \frac{\sqrt{3}}{2} {I}_{c} ) .$$

an orthogonal coordinate system is established to draw the corresponding standard stator current circular signal diagram with the d-axis component I_{d} of each fault-free three-phase current as the abscissa and the q-axis component I_{q} of each fault-free three-phase current as the ordinate.

Specifically, assuming the three-phase current signal I includes an a-phase current signal I_{α}, a b-phase current signal I_{b}, and a c-phase current signal I_{c}, the three-phase current signal can be expressed as a complex vector:

I=I_{α}+jI_{b}+j²I_{c} (1)

In the formula, j is a imaginary unit.

The complex vector is then transformed into components on two orthogonal axes, including the d-axis and q-axis.

Firstly, the d-axis component is defined as the mean value of the three-phase current, that is:

$${I}_{d} = \frac{2}{3} ( {I}_{a} - \frac{1}{2} {I}_{b} - \frac{1}{2} {I}_{c} ) \qquad ( 2 )$$

Then, the q-axis component is defined as the imbalance of three-phase current, that is:

$${I}_{q} = \frac{2}{3} ( \frac{\sqrt{3}}{2} {I}_{b} - \frac{\sqrt{3}}{2} {I}_{c} ) \qquad ( 3 )$$

By performing Clarke transformation on all fault-free three-phase current signals of the sampling points in the above manner, the d-axis component and the q-axis component for each fault-free three-phase current signal are obtained. The d-axis signal is taken as the Alpha signal, and the q-axis signal as the Beta signal. Then the Alpha signal is used as the abscissa, and the Beta signal as the ordinate to draw the corresponding standard stator current circular signal diagram, as shown in FIG. 3.

Similarly, for the alternating current motor under test, the plurality of three-phase current signals under test of an alternating current motor under test are obtained, and the plurality of three-phase current signals under test are transformed into an initial stator current circular signal scatter diagram under test.

Wherein, the method of transforming the plurality of three-phase current signals under test into an initial stator current circular signal scatter diagram under test can refer to the method of transforming the plurality of fault-free three-phase current signals into a standard stator current circular signal scatter diagram mentioned above, which will not be repeated here.

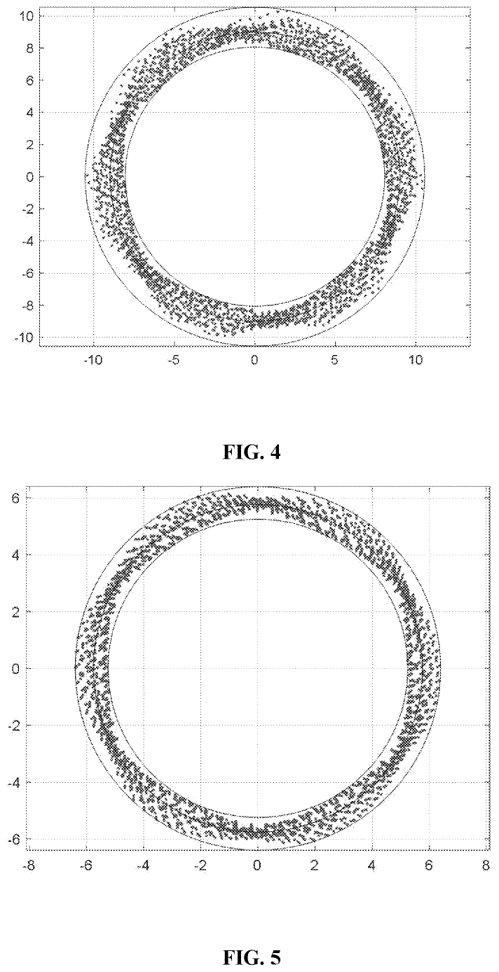

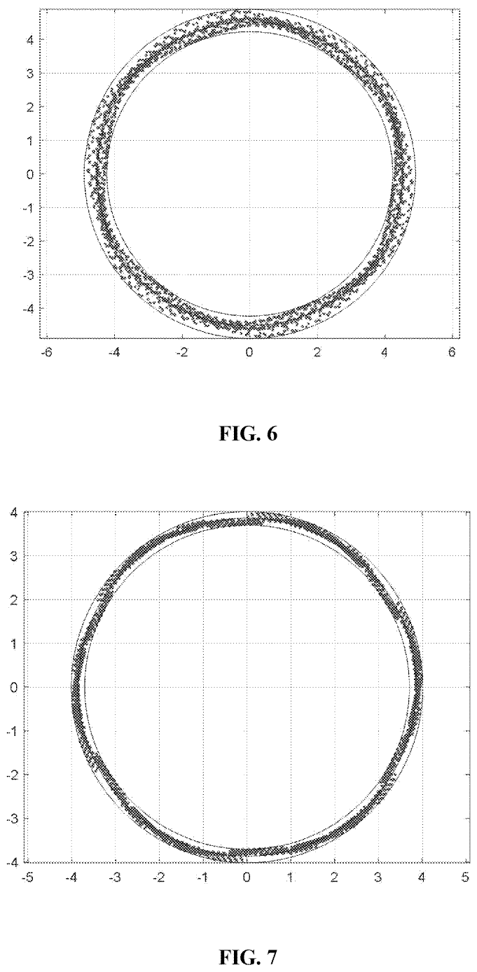

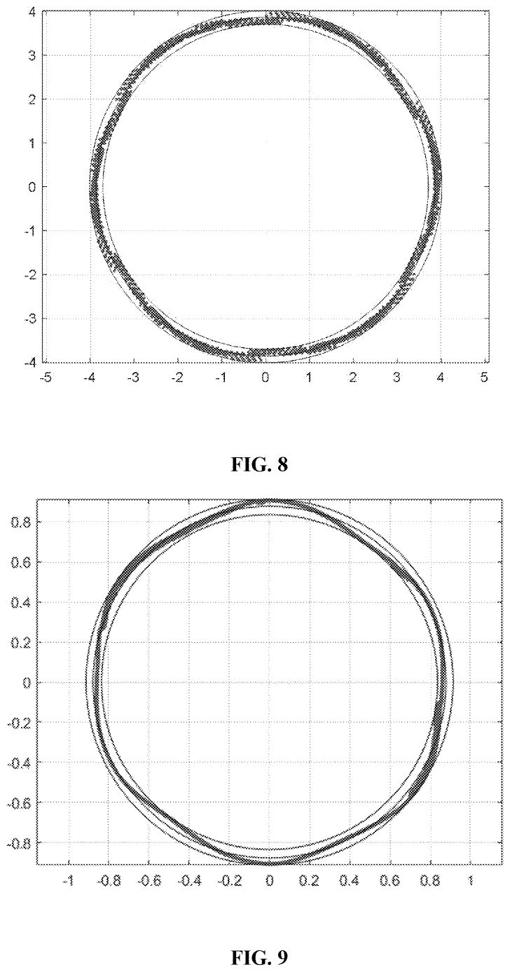

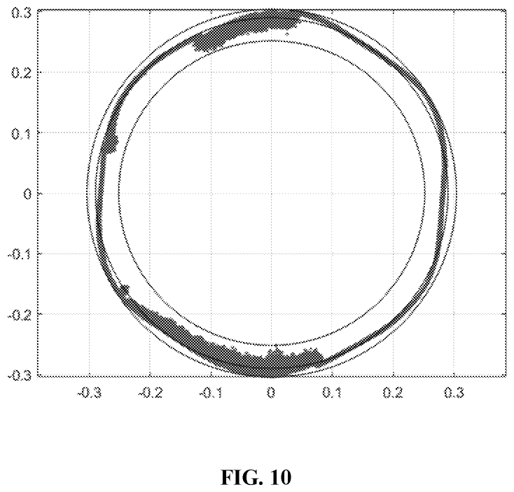

Stator current circular signal diagrams under test corresponding to alternating current motors with different faults are shown in FIG. 4 to FIG. 10. It can be understood that for an alternating current motor with the same fault, the stator current circular signal diagram determined using current data sampled at different times may vary.

S111: determine angles between signal points in the initial stator current circular signal scatter diagram under test and a preset direction vector, and sort the signal points on the basis of the angles to obtain a target stator current circular signal scatter diagram under test.

It can be understood that the standard stator current circular signal scatter diagram represents the ideal operating state of the alternating current motor. Therefore, the stator current circular signal diagram under test can be compared with the standard stator current circular signal scatter diagram. If the two circular signal diagrams are very close, the motor under test can be considered to be in normal working condition. If there are significant differences between the two circular signal diagrams, it may indicate that the motor under test has a fault or an abnormal condition.

In practical applications, the plurality of three-phase current signals under test are generated after multiple rotations of the motor. To more accurately detect the health state of the motor under test, the present disclosure re-sorts the signal points in the initial stator current circular signal scatter diagram under test to obtain the target stator current circular signal scatter diagram under test.

In one embodiment, determining angles between each signal point in the initial stator current circular signal scatter diagram under test and a preset direction vector includes:

The modulus of the current vector are determined on the basis of the coordinates of the current signal points and the coordinate of the origin in the initial stator current circular signal scatter diagram under test for any current vector formed by a current signal point and the origin in the initial stator current circular signal scatter diagram under test.

The modulus of the preset direction vector are determined.

The dot product between the preset direction vector and the current vector is determined.
the angle between the current vector and the preset direction vector is determined on the basis of the modulus of the current vector, the modulus of the preset direction vector, and the dot product between the preset direction vector and the current vector.

Specifically, a direction vector (e.g., (0, −1)) is preset. The angle between each signal point in the initial diagram and this direction vector is determined, and the signal points are re-sorted in ascending order of the angles. Since the re-sorted signal points can more accurately describe the rotation of the motor under test, the motor's operating state can be determined more accurately.

It can be understood that the coordinates of each signal point in the initial stator current circular signal scatter diagram under test are consistent, a vector can be formed between each signal point and the origin. Therefore, for any current signal point, the current vector formed by the current signal point and the origin in the initial stator current circular signal scatter diagram under test can first be determined based on the coordinates of the signal points, then, the modulus of the direction vector and the modulus of the current vector are determined respectively. Based on the modulus and the dot product between the direction vector and the current vector, the angle between the current vector and the direction vector is determined.

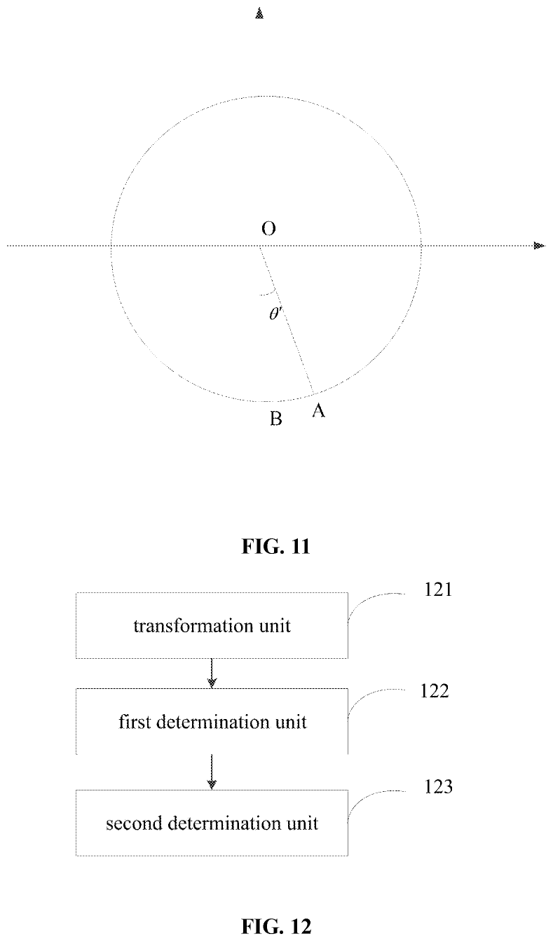

For example, referring to FIG. 11, for any current signal point A, assume that the coordinate of A is (x₁, y₁), the coordinate of the origin O is (0, 0), and the direction vector OB is (0, −1). Then the modulus of the current vector |OA| is:

$$\vert OA \vert = \sqrt{{x}_{1}^{2} + {y}_{1}^{2}} \qquad ( 1 )$$

The modulus of the direction vector |OB| is:

|OB|=\sqrt{0²+(−1)²} (2)

The dot product OA·OB between the current vector OA and the direction vector OB is

OA·OB=x₁*0+y₁*(−1) (3)

Then, the radian θ between the current vector and the direction vector is determined according to the formula (4):

$$θ = arc cos \frac{OA \cdot OB}{\vert OA \vert \vert OB \vert} \qquad ( 4 )$$

Since the calculation result θ is in radians, it must be transformed to the corresponding angle using formula (5) θ′:

$${θ}^{′} = \frac{θ}{π} ⋆ 180 \qquad ( 5 )$$

According to the above method, the angle of each signal point in initial stator current circular signal scatter diagram under test can be determined.

It should be noted that when invoking a function to calculate the angle of each signal point, if the angle of the signal point is greater than 180 degrees, the output value of the function is the supplementary angle of the angle between the signal point and the direction vector. In this case, the angular difference between all signal points and the direction vector cannot be accurately reflected. To avoid this situation from happening, when determining the angle of each signal point, the present disclosure divides the initial stator current circular signal scatter diagram under test into a positive half-region and a negative half-region, and calculates the angle of each signal point separately. Wherein The positive half-region ie the area obtained by rotating the 270 degrees axis counterclockwise by 180 degrees (the region to the right of the vertical axis); the negative half-region is the opposite, i.e., the region to the left of the vertical axis.

After the angle of each signal point is determined, the signal points are re-sorted in ascending order of angles, starting from the direction vector, to form a target stator current circular signal scatter diagram under test.

Similarly, for the standard stator current circular signal scatter diagram, it is also necessary to perform preprocessing for the standard stator current circular signal scatter diagram using the same method described above. That is, it is necessary to determine the angle of each signal point in the standard stator current circular signal scatter diagram, and then re-sort the signal points in the standard stator current circular signal scatter diagram in ascending order of angles, starting from the direction vector. The determination method is completely the same as described above, and thus will not be repeated here.

S112: perform region division on the target stator current circular signal scatter diagram under test on the basis of a preset angle threshold to obtain a plurality of first scatter regions, and divide a preprocessed standard stator current circular signal scatter diagram on the basis of the preset angle threshold to obtain a plurality of second scatter regions.

To reduce the determination error of the health state of the motor under test, the present disclosure divides the target stator current circular signal scatter diagram under test into multiple first scatter regions according to the preset angle threshold, and divides the preprocessed standard stator current circular signal scatter diagram into multiple second scatter regions according to the angle threshold. The number of the first scatter regions is consistent with the number of the second scatter regions.

For example, when the angle threshold is 40 degrees, there are 9 first scatter regions and 9 second scatter regions. When the angle threshold is 45 degrees, there are 8 first scatter regions and 8 second scatter regions.

In this way, the data in each small scatter region can be analyzed on a per-scatter-region basis, ensuring the thoroughness of data analysis and minimizing errors. For example, after dividing the stator current circular signal scatter diagram under test into multiple portions, the data characteristics within each angle range can be more comprehensively understood, the data variation trends within each angle range can be analyzed, and subtle differences or abnormalities can be discovered, thereby improving the reliability of the assessment.

S113: determine health evaluation parameters on the basis of first coordinates of each signal point in each first scatter region and second coordinates of each signal point in each second scatter region.

The health evaluation parameters in the present disclosure may include multiple types. For example, the health evaluation parameters may include: center of gravity offset and radius standard deviation; or may include: kurtosis value, skewness value, and root mean square value. Different types of health evaluation parameters have different determination methods, as specifically implemented below.

In one embodiment, when the health evaluation parameters include a center of gravity offset and a radius standard deviation, the health evaluation parameters are determined on the basis of the first coordinates of each signal point in each first scatter region and the second coordinates of each signal point in each second scatter region, including:

The first center of gravity offset for each first scatter region and the first radius for each signal point in each first scatter region are determined based on the first coordinates of each signal point in each first scatter region; the mean of the first center of gravity offsets is determined as the current center of gravity offset of the target stator current circular signal scatter diagram under test.

The second center of gravity offset for each second scatter region and the second radius for each signal point in each second scatter region are determined based on the second coordinates of each signal point in each second scatter region; and the mean of the second center of gravity offsets is determined as the reference center of gravity offset.

The first radius standard deviation for each first scatter region is determined based on the first radius for each signal point in each first scatter region; and the mean of the first radius standard deviations is determined as the current radius standard deviation of the target stator current circular signal scatter diagram under test.

The second radius standard deviation for each second scatter region is determined based on the second radius for each signal point in each second scatter region; and the mean of the second radius standard deviations is determined as the reference radius standard deviation of the preprocessed standard stator current circular signal scatter diagram.

Specifically, due to the fact that the determination method of the current center of gravity offset is completely the same as that of the reference center of gravity offset, the current center of gravity offset is used as an example for detailed description below.

It can be understood that after the Clarke transformation, the first coordinates of each signal point in each first scatter region can be directly obtained. Therefore, for any first scatter region, the horizontal coordinate of the center of gravity of the first scatter region xₐₖ can be determined based on formula (6), and the vertical coordinate of the center of gravity of the first scatter region yₐₖ can be determined based on formula (7).

$${x}_{a} = \frac{{\sum }_{j = 1}^{n} {m}_{j} \cdot {x}_{j}}{{\sum }_{j = 1}^{n} {m}_{j}} \qquad ( 6 )$$

$${y}_{a} = \frac{{\sum }_{j = 1}^{n} {m}_{j} \cdot {y}_{j}}{{\sum }_{j = 1}^{n} {m}_{j}} \qquad ( 7 )$$

Wherein, mⱼ is the quality of the j-th signal point in each first scatter region, which defaults to 1; xⱼ is the horizontal coordinate of the j-th signal point in each first scatter region, and yⱼ is the vertical coordinate of the j-th signal point in each first scatter region.

Then, the center of gravity offset for each first scatter region Rₜ is determined according to formula (8).

Rₜ=\sqrt{(x_{α}−x₀)²+(y_{α}−y₀)²} (8)

In formula (8), x₀ to is the horizontal coordinate of the center of the target stator current circular signal scatter diagram under test, and y₀ is the vertical coordinate of the center of the target stator current circular signal scatter diagram under test.

If there are multiple first scatter points, multiple center of gravity offsets Rₜ can be determined, and the mean of the multiple center of gravity offsets can be taken as the current center of gravity offset R_{T}.

The reference center of gravity offset

$${R}_{T}^{′}$$

can be determined in the same way as described above, and will not be repeated here.

Due to the fact that the determination method of the current radius standard deviation and the reference radius standard deviation is completely the same, the current radius standard deviation is used as an example for detailed description below.

First, the first radius deviation of each signal point in each first scatter region Rᵤ is determined according to formula (9).

$${R}_{u} = \frac{E \{ {[ {r}_{j} - {μ}_{k} ]}^{4} \}}{{σ}_{k}^{4} \cdot {μ}_{k}} \qquad ( 9 )$$

In formula (9), rⱼ is the first radius of the j-th signal point in the first scatter region, μₖ is the mean radius of all signal points in the k-th first scatter region, and σₖ is the variance of the radii of all signal points in the k-th first scatter region.

Then take the mean of the first radius deviations in each first scatter region as the second radius deviation

$${R}_{u}^{′}$$

for that first scatter region;

Finally, the mean of the second radius deviation of each first scatter region is determined as the current radius deviation of the target stator current circular signal scatter diagram under test.

The reference radius offset

$${R}_{U}^{′}$$

can be determined in the same way as described above, and will not be repeated here.

In one embodiment, when the health evaluation parameters include a kurtosis value, a skewness value, and a root mean square value, the health evaluation parameters are determined on the basis of the first coordinates of each signal point in each first scatter region and the second coordinates of each signal point in each second scatter region, including:
the first radii of all signal points in each first scatter region are determined, and the minimum first radius is identified from the first radii of all the signal points;
the distance differences between the first radii of each remaining signal point in each first scatter region and the minimum first radius are obtained; the remaining signal points in the first scatter region are all signal points in the first scatter region except for the signal point corresponding to the minimum first radius;
the kurtosis value of the distance difference, the skewness value of the distance difference, and the root mean square value of the distance difference in each first scatter region are determined based on all the distance differences in each first scatter region;
the second radii of all signal points in each second scatter region are determined, and the minimum second radius are determined from the second radii of all the signal points;
the distance differences between the second radii of each remaining signal point in each second scatter region and the minimum second radius are obtained; the remaining signal points in the second scatter region are all signal points in the second scatter region except for the signal point corresponding to the minimum second radius; and
the kurtosis value of the distance difference, the skewness value of the distance difference, and the root mean square value of the distance difference in each second scatter region are determined based on all the distance differences in each second scatter region.

In one embodiment, the kurtosis value of the distance difference, the skewness value of the distance difference, and the root mean square value of the distance difference in each first scatter region are determined, including:

The kurtosis value of the distance difference in each first scatter region is determined according to formula (10);

$$χ = \frac{1}{N} {\sum }_{i = 1}^{N} {d}_{i}^{4} \qquad ( 10 )$$

The skewness value of the distance difference in each first scatter region is determined according to formula (11);

$$γ = \frac{1}{N} {\sum }_{i = 1}^{N} {d}_{i}^{3} \qquad ( 11 )$$

The root mean square value of the distance difference in each first scatter region is determined according to formula (12);

$${X}_{rms} = \sqrt{\frac{1}{N} {\sum }_{i = 1}^{N} {d}_{i}^{2}} \qquad ( 12 )$$

Wherein, N is the number of distance differences in the first scatter region, i is the sequence number of distance differences in the first scatter region, and dᵢ is the i-th distance difference.

Specifically, the determination method for determining the parameter matrix under test and the reference parameter matrix is the same. Here, the parameter matrix under test is used as an example for illustration.

In each first scatter region, the number of signal points contained in the first scatter region may first be determined. For example, in the first scatter region of 0 degrees to 40 degrees, the number of signal points in that first scatter region of 0 degrees to 40 degrees can be determined by counting the number of signal points whose angle is less than 40 degrees.

Then, since the coordinates of each signal point in the target stator current circular signal scatter diagram under test are known, the corresponding first radius can be determined according to the coordinates of each signal point.

In each first scatter region, the minimum first radius is determined, and the distance differences between each remaining first radius and the minimum first radius are determined.

To accurately describe the difference between the target stator current circular signal scatter diagram under test and the standard stator current circular signal scatter diagram, the present disclosure uses the kurtosis value, skewness value, and root mean square value of the distance difference for difference characterization.

Therefore, for each first scatter region, the kurtosis value, the skewness value of the distance difference, and the root mean square value of the distance difference in that scatter region need to be determined according to the above formulas (10) to (12). Assuming the number of first scatter regions is 9, then 9 sets of the kurtosis value, the skewness value of the distance difference, and the root mean square value of the distance difference can ultimately be obtained. A parameter matrix under test is constructed based on these 9 sets of kurtosis values, skewness values, and root mean square values.

For example, in the first scatter region, if the kurtosis value of the distance difference is χ₁, the skewness value is γ₁, the root mean square value is γ₁, and so on, and in the ninth first scatter region, the kurtosis value of the distance difference is χ₉, the skewness value is γ₉, and the root mean square value is Xᵣₘₛ₉, then the parameter matrix P1 under test is:

$$P 1 = [ \begin{matrix}{χ}_{1} & {γ}_{1} & {X}_{rms 1} \\ ⋮ & ⋱ & ⋮ \\ {χ}_{9} & {γ}_{9} & {X}_{rms 9}\end{matrix} ]$$

Similarly, for each second scatter region in the standard stator current circular signal scatter diagram, the reference parameter matrix can be constructed in the same manner as described above, and will not be repeated here.

Thus, all health evaluation parameters are determined.

S114: on the basis of the health evaluation parameters, determine a health score of the alternating current motor under test; and on the basis of the health score, evaluate the health state of the alternating current motor under test.

After the health evaluation parameters are determined, the health score of the alternating current motor under test is determined on the basis of the health evaluation parameters, and the health state of the alternating current motor under test is evaluated on the basis of the health score.

It should be noted that when different types of health evaluation parameters are used to determine the health score of the alternating current motor under test, the determination methods are also different.

If the health evaluation parameters include: center of gravity offset and radius standard deviation, the health score of the alternating current motor under test is determined based on the health evaluation parameters, including:

The reference evaluation value η of the preprocessed standard stator current circular signal scatter diagram is determined according to the formula η={square root over (R_{U}−0.6R_{T})²)}.

The current evaluation value η′ of the target stator current circular signal scatter diagram under test is determined according to the formula

$${η}^{′} = \sqrt{{( {R}_{U}^{′} - 0.6 {R}_{T}^{′} )}^{2}} .$$

The health score ζ of the alternating current motor under test is determined according to the formula

$$ζ = 100 - \frac{\vert {η}^{′} - η \vert}{γ} .$$

Wherein, R_{U} is the reference radius standard deviation, R_{T} is the reference center of gravity offset,

$${R}_{U}^{′}$$

is the current radius standard deviation,

$${R}_{T}^{′}$$

is the current center of gravity offset, and γ is the reference score corresponding to the preprocessed standard stator current circular signal scatter diagram.

In one embodiment, if the health evaluation parameters include: kurtosis value of the distance difference, skewness value of the distance difference, and root mean square value of the distance difference, the health score of the alternating current motor under test is determined according to the health evaluation parameters, including:
the parameter matrix under test is constructed based on the kurtosis value of the distance difference, the skewness value of the distance difference, and root mean square value of the distance difference in each first scatter region;
the reference parameter matrix is constructed based on the kurtosis value of the distance difference, the skewness value of the distance difference, and root mean square value of the distance difference in each second scatter region;
the similarity coefficient between the parameter matrix under test and the reference parameter matrix is determined; and
the health score S of the alternating current motor under test is determined based on the formula

$$S = \frac{{η}^{″} - 0.7}{( 1 - 0 \text{.7} ) * 0.01} ,$$

wherein, η″ is the similarity coefficient.

In one embodiment, determining the similarity coefficient between the parameter matrix under test and the reference parameter matrix includes:
the covariance between the parameter matrix under test and the reference parameter matrix is determined;
the first standard deviation of the parameter matrix under test and the second standard deviation of the reference parameter matrix are determined;
the product value of the first standard deviation and the second standard deviation is determined; and
the similarity coefficient between the parameter matrix under test and the reference parameter matrix according to the covariance and the product value of the first standard deviation and the second standard deviation; the similarity coefficient is the quotient of the covariance divided by the product value.

Specifically, when determining the first standard deviation of the parameter matrix under test, the mean of all elements in the parameter matrix under test may first be determined, then the square of the difference between each element and the mean is determined, the sum of all squared values is calculated, and the sum is divided by the number of elements in the parameter matrix under test to obtain the first standard deviation of the parameter matrix under test.

Similarly, the second standard deviation of the reference parameter matrix can be determined in the above manner, and will not be repeated here.

Then the product value of the first standard deviation and the second standard deviation is determined, and the covariance is divided by the product value to obtain the similarity coefficient.

Finally, the health state of the alternating current motor under test can be evaluated according to the health score of the alternating current motor under test, including:

If it is determined that the health score is greater than or equal to a preset health threshold, then it is determined that the health state of the alternating current motor is good.

If it is determined that the health score is less than the preset health threshold, then it is determined that the health state of the alternating current motor is poor and may be in an abnormal working state.

The health threshold may be set based on actual conditions, for example, 60, and is not limited herein.

Based on the collected stator currents, the Clarke transformation is used to transform the multiple fault-free three-phase current signals of the normal alternating current motor into a standard stator current circular signal scatter diagram, and to transform the multiple three-phase current signals under test of the alternating current motor under test into a stator current circular signal diagram under test; then the similarity between the stator current circular signal diagram under test and the standard stator current circular signal diagram is compared, and the health score of the alternating current motor is quantified using the similarity, so that the health state of the motor can be accurately evaluated according to the health score.

Based on the same inventive concept as the previous embodiments, the present embodiment also provides an apparatus for evaluating the health state of a marine alternating current motor. As shown in FIG. 12, the apparatus includes: a transformation unit 121, a first determination unit 122, and a second determination unit 123.

The transformation unit 121 is configured to obtain a plurality of fault-free three-phase current signals of a normal alternating current motor, transform the plurality of fault-free three-phase current signals into a standard stator current circular signal scatter diagram using the Clarke transformation; obtain a plurality of three-phase current signals under test of an alternating current motor under test, and transform the plurality of three-phase current signals under test into an initial stator current circular signal scatter diagram under test.

The first determination unit 122 is configured to determine angles between each signal point in the initial stator current circular signal scatter diagram under test and a preset direction vector, sort the signal points on the basis of the angles to obtain a target stator current circular signal scatter diagram under test; perform region division on the target stator current circular signal scatter diagram under test on a basis of a preset angle threshold to obtain a plurality of first scatter regions, and divide a preprocessed standard stator current circular signal scatter diagram on the basis of the angle threshold to obtain a plurality of second scatter regions.

The second determination unit 123 is configured to determine health evaluation parameters on a basis of the first coordinates of each signal point in each first scatter region and second coordinates of each signal point in each second scatter region; determine a health score of the alternating current motor under test on the basis of the health evaluation parameters; and evaluate the health state of the alternating current motor under test on the basis of the health score.

Since the apparatus introduced in the embodiments of the present disclosure is the apparatus used to implement the method for evaluating a health state of a marine alternating current motor according to the embodiments of the present disclosure, based on the method introduced in the embodiments of the present disclosure, those skilled in the art can understand the specific structure and variations of the apparatus, and thus will not be repeated here. Any apparatus adopting the method of the embodiments of the present disclosure falls within the protection scope of the present disclosure.

Based on the same inventive concept, the present embodiment provides a computer device, including a memory, a processor, and a computer program stored on the memory and executable on the processor, wherein the processor implements any step of the above-described methods when executing the computer program.

Based on the same inventive concept, the present embodiment provides a computer-readable storage medium storing a computer program stored thereon, when the computer program is executed by the processor, the steps of any of the methods described above can be implemented.

Through one or more embodiments of the present disclosure, the present disclosure has the following beneficial effects or advantages.

The present disclosure provides a method, an apparatus, a medium, and a device for evaluating health state of a marine alternating current motor. The method includes: obtaining a plurality of fault-free three-phase current signals of a normal alternating current motor, and using Clarke transformation to transform the plurality of fault-free three-phase current signals into a standard stator current circular signal scatter diagram; obtaining a plurality of three-phase current signals under test of an alternating current motor under test, and transforming the plurality of three-phase current signals under test into an initial stator current circular signal scatter diagram under test; determining angles between each signal point in the initial stator current circular signal scatter diagram under test and a preset direction vector, and sorting the signal points on the basis of the angles to obtain a target stator current circular signal scatter diagram under test; performing region division on the target stator current circular signal scatter diagram under test on a basis of a preset angle threshold to obtain a plurality of first scatter regions, and dividing a preprocessed standard stator current circular signal scatter diagram on the basis of the angle threshold to obtain a plurality of second scatter regions; determining health evaluation parameters on a basis of first coordinates of each signal point in each first scatter region and second coordinates of each signal point in each second scatter region; and determining a health score of the alternating current motor under test on the basis of the health evaluation parameters, and evaluating the health state of the alternating current motor under test on the basis of the health score. In this way, based on the collected stator currents, the Clarke transformation is used to transform the multiple fault-free three-phase current signals of the normal alternating current motor into a standard stator current circular signal scatter diagram, and to transform the multiple three-phase current signals under test of the alternating current motor under test into a stator current circular signal diagram under test; health evaluation parameters are determined according to the coordinates of each signal point in each scatter region, and the health score of the alternating current motor is quantified using the health evaluation parameters, thereby enabling accurate evaluation of the motor's health state based on the health score.

The algorithms and displays provided herein are not inherently related to any particular computer, virtual system, or other device. Various general-purpose systems may also be used with the teachings based on the description herein. The required structure for constructing such systems is obvious according to the above description. Furthermore, the present disclosure is not directed to any particular programming language. It should be understood that the content of the present disclosure described herein may be implemented using various programming languages, and the description of specific languages above is for disclosing the best embodiment of the present disclosure.

Numerous specific details are explained in the description provided herein. However, it can be understood that embodiments of the present disclosure may be practiced without these specific details. In some examples, well-known methods, structures, and techniques have not been shown in detail in order not to obscure the understanding of this description.

Similarly, it should be understood that, in order to streamline the present disclosure and aid in the understanding one or more aspects of the present disclosure, various features of the present disclosure are sometimes grouped together into a single embodiment, a figure, or the description thereof. However, this method of disclosure should not be interpreted as reflecting the following intention that the claimed invention requires more features than those explicitly stated in each claim. Rather, as the following claims reflect, the aspects of the present disclosure lie in having fewer than all features of the single foregoing disclosed embodiment. Thus, the claims following the specific implementation mode are hereby expressly incorporated into the specific implementation mode, with each claim standing on its own as a separate embodiment of the present disclosure.

Those skilled in the art will understand that the modules in the devices of the embodiments may be adaptively changed and arranged in one or more devices different from that embodiment. Modules, units, or components in an embodiment may be combined into one module, ond unit, or one component, and furthermore may be divided into a plurality of sub-modules, sub-units, or sub-components. All features disclosed in this specification (including the accompanying claims, abstract, and drawings), and all processes or units of any method or device disclosed herein, may be combined in any combination, except for at least some of the features and/or processes or units that are mutually exclusive. Unless expressly stated otherwise, each feature disclosed in this specification (including the accompanying claims, abstract, and drawings) may be replaced by an alternative feature serving the same purpose, the equivalent purpose, or the similar purpose.

Furthermore, those skilled in the art will appreciate that although some embodiments described herein include certain features that are not included in other embodiments, combinations of features of different embodiments are meant to be within the scope of the disclosure and form different embodiments. For example, in the following claims, any of the claimed embodiments for protection may be used in any combination.

Various component embodiments of the present disclosure may be implemented in hardware, or as software modules running on one or more processors, or as a combination thereof. Those skilled in the art will understand that a microprocessor or a digital signal processor (DSP) may be used in practice to implement some or all of the functions of some or all of the components of the gateway, proxy server, or system according to embodiments of the disclosure. The present disclosure may also be implemented as a device or an apparatus program (e.g., a computer program and a computer program product) for performing part or all of the methods described herein. The program for implementing the present disclosure in this way can be stored on a computer-readable medium or can take the form of one or more signals. Such signals may be downloaded from an Internet website, provided on a carrier signal, or provided in any other form.

It should be noted that the above embodiments illustrate rather than limit the present disclosure, and that those skilled in the art may design alternative embodiments without departing from the scope of the appended claims. In the claims, any reference signs placed between parentheses shall not be construed as limiting the claim. The word “comprising” does not exclude the presence of elements or steps not listed in a claim. The word “a” or “an” preceding an element does not exclude the presence of a plurality of such elements. The present disclosure may be implemented by means of hardware including several distinct elements, and by means of a suitably programmed computer. In the unit claims listing several devices, several of these devices may be specifically embodied through the same hardware item. The use of words such as first, second, and third does not indicate any order. These words can be interpreted as names.

Although preferred embodiments of the present disclosure have been described, those skilled in the art, once they understand the basic inventive concept, may make additional changes and modifications to these embodiments. Therefore, the appended claims are intended to be interpreted as including the preferred embodiments and all changes and modifications that fall within the scope of the present disclosure.

The above description is only of preferred embodiments of the present disclosure and is not intended to limit the scope of protection of the present disclosure. Any modifications, equivalent substitutions, and improvements made within the spirit and principle of the present disclosure shall be included in the scope of protection of the present disclosure.

What is claimed is:

1. A method for evaluating a health state of a marine alternating current motor, comprising:
obtaining a plurality of fault-free three-phase current signals of a normal alternating current motor, and using Clarke transformation to transform the plurality of fault-free three-phase current signals into a standard stator current circular signal scatter diagram;
obtaining a plurality of three-phase current signals under test of an alternating current motor under test, and transforming the plurality of three-phase current signals under test into an initial stator current circular signal scatter diagram under test;
determining angles between each signal point in the initial stator current circular signal scatter diagram under test and a preset direction vector, and sorting the signal points on the basis of the angles to obtain a target stator current circular signal scatter diagram under test;
performing region division on the target stator current circular signal scatter diagram under test on a basis of a preset angle threshold to obtain a plurality of first scatter regions, and dividing a preprocessed standard stator current circular signal scatter diagram on the basis of the angle threshold to obtain a plurality of second scatter regions;
determining health evaluation parameters on a basis of first coordinates of each signal point in each first scatter region and second coordinates of each signal point in each second scatter region; and
determining a health score of the alternating current motor under test on the basis of the health evaluation parameters; and evaluating the health state of the alternating current motor under test on the basis of the health score; wherein
if the health evaluation parameters comprise: center of gravity offset and radius standard deviation, the determining health evaluation parameters on a basis of first coordinates of each signal point in each first scatter region and second coordinates of each signal point in each second scatter region comprises:
determining a first center of gravity offset for each first scatter region and a first radius for each signal point in each first scatter region based on the first coordinates of each signal point in each first scatter region; determining a mean of the first center of gravity offsets as a current center of gravity offset of the target stator current circular signal scatter diagram under test;
determining a second center of gravity offset for each second scatter region and a second radius for each signal point in each second scatter region based on the second coordinates of each signal point in each second scatter region; determining a mean of the second center of gravity offsets as a reference center of gravity offset;
determining first radius standard deviations for each first scatter region based on the first radius for each signal point in each first scatter region; determining a mean of the first radius standard deviations as a current radius standard deviation of the target stator current circular signal scatter diagram under test; and
determining second radius standard deviations for each second scatter region based on the second radius for each signal point in each second scatter region; determining a mean of the second radius standard deviations as a reference radius standard deviation of the preprocessed standard stator current circular signal scatter diagram.

2. The method according to claim 1, wherein the determining angles between each signal point in the initial stator current circular signal scatter diagram under test and a preset direction vector comprises:
determining a modulus of the current vector on a basis of the coordinates of current signal points and coordinate of an origin in the initial stator current circular signal scatter diagram under test for any current vector formed by a current signal point and an origin in the initial stator current circular signal scatter diagram under test;
determining a modulus of the preset direction vector;
determining a dot product between the preset direction vector and the current vector; and
determining an angle between the current vector and the preset direction vector on the basis of the modulus of the current vector, the modulus of the preset direction vector, and the dot product between the preset direction vector and the current vector.

3. The method according to claim 1, wherein if the health evaluation parameters comprise kurtosis value, skewness value, and root mean square value, the determining health evaluation parameters on a basis of first coordinates of each signal point in each first scatter region and second coordinates of each signal point in each second scatter region comprises:
determining first radii of all signal points in each first scatter region, and identifying a minimum first radius from the first radii of all the signal points;
obtaining a distance difference between the first radius of each remaining signal point in each first scatter region and the minimum first radius; the remaining signal points in the first scatter region are all signal points in the first scatter region except for the signal point corresponding to the minimum first radius;
determining the kurtosis value of the distance difference, the skewness value of the distance difference, and the root mean square value of the distance difference in each first scatter region based on all the distance differences in each first scatter region;
determining second radii of all signal points in each second scatter region, and identifying a minimum second radius from the second radii of all the signal points;
obtaining a distance differences between the second radii of each remaining signal point in each second scatter region and the minimum second radius; the remaining signal points in the second scatter region are all signal points in the second scatter region except for the signal point corresponding to the minimum second radius; and
determining the kurtosis value of the distance difference, the skewness value of the distance difference, and the root mean square value of the distance difference in each second scatter region based on all the distance differences in each second scatter region.

4. The method according to claim 1, wherein the determining the health score of the alternating current motor under test on the basis of the health evaluation parameters comprises:
determining a reference evaluation value η for the preprocessed standard stator current circular signal scatter diagram according to a formula η=\sqrt{(R_{U}−0.6R_{T})²};
determining a current evaluation value η′ for the target stator current circular signal scatter diagram under test according to a formula
$${η}^{′} = \sqrt{{( {R}_{U}^{′} - 0.6 {R}_{T}^{′} )}^{2}} ;$$
and
determining the health score ζ for the alternating current motor under test according to a formula
$$ς = 100 - \frac{\vert {η}^{′} - η \vert}{γ} ;$$
wherein
R_{U} is the reference radius standard deviation, R_{T} is the reference center of gravity offset,
$${R}_{U}^{′}$$
is the current radius standard deviation,
$${R}_{T}^{′}$$
is the current center of gravity offset, γ is a reference score corresponding to the preprocessed standard stator current circular signal scatter diagram.

5. The method according to claim 3, wherein the determining a health score of the alternating current motor under test on the basis of the health evaluation parameters comprises:
constructing a parameter matrix under test based on the kurtosis value of the distance difference, the skewness value of the distance difference, and the root mean square value of the distance difference in each first scatter region;
constructing a reference parameter matrix based on the kurtosis value of the distance difference, the skewness value of the distance difference, and the root mean square value of the distance difference in each second scatter region;
determining a similarity coefficient between the parameter matrix under test and the reference parameter matrix; and
determining the health score S of the alternating current motor under test based on a formula
$$S = \frac{{η}^{″} - 0.7}{( 1 - 0.7 ) * 0.01} ,$$
wherein η″ is the similarity coefficient.

6. The method according to claim 5, wherein the determining the similarity coefficient between the parameter matrix under test and the reference parameter matrix comprises:
determining a covariance between the parameter matrix under test and the reference parameter matrix;
determining a first standard deviation of the parameter matrix under test and a second standard deviation of the reference parameter matrix;
determining a product value of the first standard deviation and the second standard deviation; and
determining the similarity coefficient between the parameter matrix under test and the reference parameter matrix according to the covariance and the product value of the first standard deviation and the second standard deviation; the similarity coefficient is a quotient between the covariance and the product value.

7. The method according to claim 3, wherein the determining the kurtosis value of the distance difference, the skewness value of the distance difference, and the root mean square value of the distance difference in each first scatter region comprises:
determining the kurtosis value χ of the distance difference in each first scatter region according to the formula
$$χ = \frac{1}{N} {\sum }_{i = 1}^{N} {d}_{i}^{4} ;$$
determining the skewness value γ of the distance difference in each first scatter region according to the formula
$$γ = \frac{1}{N} {\sum }_{i = 1}^{N} {d}_{i}^{3} ;$$
determining the root mean square value Xᵣₘₛ of the distance difference in each first scatter region according to the formula
$${X}_{rms} = \sqrt{\frac{1}{N} {\sum }_{i = 1}^{N} {d}_{i}^{2}} ;$$
wherein
N is a number of distance differences in the first scatter region, i is a index of the distance difference in the first scatter region, dᵢ is the i-th distance difference.

8. An apparatus for evaluating a health state of a marine alternating current motor, comprising:
a transformation unit, configured to obtain a plurality of fault-free three-phase current signals of a normal alternating current motor, and transform the plurality of fault-free three-phase current signals into a standard stator current circular signal scatter diagram using Clarke transformation; obtain a plurality of three-phase current signals under test of an alternating current motor under test, and transform the plurality of three-phase current signals under test into an initial stator current circular signal scatter diagram under test;
a first determination unit, configured to determine angles between each signal point in the initial stator current circular signal scatter diagram under test and a preset direction vector, and sort the signal points on the basis of the angles to obtain a target stator current circular signal scatter diagram under test; perform region division on the target stator current circular signal scatter diagram under test on a basis of a preset angle threshold to obtain a plurality of first scatter regions, and divide a preprocessed standard stator current circular signal scatter diagram on the basis of the angle threshold to obtain a plurality of second scatter regions; and
a second determination unit, which is configured to determine health evaluation parameters on a basis of first coordinates of each signal point in each first scatter region and second coordinates of each signal point in each second scatter region, determine a health score of the alternating current motor under test on the basis of the health evaluation parameters, and evaluate the health state of the alternating current motor under test on the basis of the health score; wherein
if the health evaluation parameters comprise: center of gravity offset and radius standard deviation, the determining health evaluation parameters on a basis of first coordinates of each signal point in each first scatter region and second coordinates of each signal point in each second scatter region comprises:
determining a first center of gravity offset for each first scatter region and a first radius for each signal point in each first scatter region based on the first coordinates of each signal point in each first scatter region; determining a mean of the first center of gravity offsets as a current center of gravity offset of the target stator current circular signal scatter diagram under test;
determining a second center of gravity offset for each second scatter region and a second radius for each signal point in each second scatter region based on the second coordinates of each signal point in each second scatter region; determining a mean of the second center of gravity offsets as a reference center of gravity offset;
determining first radius standard deviations for each first scatter region based on the first radius for each signal point in each first scatter region; determining a mean of the first radius standard deviations as a current radius standard deviation of the target stator current circular signal scatter diagram under test; and
determining second radius standard deviations for each second scatter region based on the second radius for each signal point in each second scatter region; determining a mean of the second radius standard deviations as a reference radius standard deviation of the preprocessed standard stator current circular signal scatter diagram.

9. A computer device, comprising a memory, a processor, and a computer program stored on the memory and executable on the processor, wherein the processor implements the steps of the method of claim 1 when executing the program; wherein
the method of claim 1 comprises:
obtaining a plurality of fault-free three-phase current signals of a normal alternating current motor, and using Clarke transformation to transform the plurality of fault-free three-phase current signals into a standard stator current circular signal scatter diagram;
obtaining a plurality of three-phase current signals under test of an alternating current motor under test, and transforming the plurality of three-phase current signals under test into an initial stator current circular signal scatter diagram under test;
determining angles between each signal point in the initial stator current circular signal scatter diagram under test and a preset direction vector, and sorting the signal points on the basis of the angles to obtain a target stator current circular signal scatter diagram under test;
performing region division on the target stator current circular signal scatter diagram under test on a basis of a preset angle threshold to obtain a plurality of first scatter regions, and dividing a preprocessed standard stator current circular signal scatter diagram on the basis of the angle threshold to obtain a plurality of second scatter regions;
determining health evaluation parameters on a basis of first coordinates of each signal point in each first scatter region and second coordinates of each signal point in each second scatter region; and
determining a health score of the alternating current motor under test on the basis of the health evaluation parameters; and evaluating the health state of the alternating current motor under test on the basis of the health score; wherein
if the health evaluation parameters comprise: center of gravity offset and radius standard deviation, the determining health evaluation parameters on a basis of first coordinates of each signal point in each first scatter region and second coordinates of each signal point in each second scatter region comprises:
determining a first center of gravity offset for each first scatter region and a first radius for each signal point in each first scatter region based on the first coordinates of each signal point in each first scatter region; determining a mean of the first center of gravity offsets as a current center of gravity offset of the target stator current circular signal scatter diagram under test;
determining a second center of gravity offset for each second scatter region and a second radius for each signal point in each second scatter region based on the second coordinates of each signal point in each second scatter region; determining a mean of the second center of gravity offsets as a reference center of gravity offset;
determining first radius standard deviations for each first scatter region based on the first radius for each signal point in each first scatter region; determining a mean of the first radius standard deviations as a current radius standard deviation of the target stator current circular signal scatter diagram under test; and
determining second radius standard deviations for each second scatter region based on the second radius for each signal point in each second scatter region; determining a mean of the second radius standard deviations as a reference radius standard deviation of the preprocessed standard stator current circular signal scatter diagram.

10. The computer device according to claim 9, wherein the determining angles between each signal point in the initial stator current circular signal scatter diagram under test and a preset direction vector comprises:
determining a modulus of the current vector on a basis of the coordinates of current signal points and coordinate of an origin in the initial stator current circular signal scatter diagram under test for any current vector formed by a current signal point and an origin in the initial stator current circular signal scatter diagram under test;
determining a modulus of the preset direction vector;
determining a dot product between the preset direction vector and the current vector; and
determining an angle between the current vector and the preset direction vector on the basis of the modulus of the current vector, the modulus of the preset direction vector, and the dot product between the preset direction vector and the current vector.

11. The computer device according to claim 9, wherein if the health evaluation parameters comprise kurtosis value, skewness value, and root mean square value, the determining health evaluation parameters on a basis of first coordinates of each signal point in each first scatter region and second coordinates of each signal point in each second scatter region comprises:
determining first radii of all signal points in each first scatter region, and identifying a minimum first radius from the first radii of all the signal points;
obtaining a distance difference between the first radius of each remaining signal point in each first scatter region and the minimum first radius; the remaining signal points in the first scatter region are all signal points in the first scatter region except for the signal point corresponding to the minimum first radius;
determining the kurtosis value of the distance difference, the skewness value of the distance difference, and the root mean square value of the distance difference in each first scatter region based on all the distance differences in each first scatter region;
determining second radii of all signal points in each second scatter region, and identifying a minimum second radius from the second radii of all the signal points;
obtaining a distance differences between the second radii of each remaining signal point in each second scatter region and the minimum second radius; the remaining signal points in the second scatter region are all signal points in the second scatter region except for the signal point corresponding to the minimum second radius; and
determining the kurtosis value of the distance difference, the skewness value of the distance difference, and the root mean square value of the distance difference in each second scatter region based on all the distance differences in each second scatter region.

12. The computer device according to claim 9, wherein the determining the health score of the alternating current motor under test on the basis of the health evaluation parameters comprises:
determining a reference evaluation value η for the preprocessed standard stator current circular signal scatter diagram according to a formula η=\sqrt{(R_{U}−0.6R_{T})²};
determining a current evaluation value η′ for the target stator current circular signal scatter diagram under test according to a formula
$${η}^{′} = \sqrt{{( {R}_{U}^{′} - 0.6 {R}_{T}^{′} )}^{2}} ;$$
and
determining the health score ζ for the alternating current motor under test according to a formula
$$ς = 100 - \frac{\vert {η}^{′} - η \vert}{γ} ;$$
wherein
R_{U} is the reference radius standard deviation, R_{T} is the reference center of gravity offset,
$${R}_{U}^{′}$$
is the current radius standard deviation,
$${R}_{T}^{′}$$
is the current center of gravity offset, γ is a reference score corresponding to the preprocessed standard stator current circular signal scatter diagram.

13. The computer device according to claim 11, wherein the determining a health score of the alternating current motor under test on the basis of the health evaluation parameters comprises:
constructing a parameter matrix under test based on the kurtosis value of the distance difference, the skewness value of the distance difference, and the root mean square value of the distance difference in each first scatter region;
constructing a reference parameter matrix based on the kurtosis value of the distance difference, the skewness value of the distance difference, and the root mean square value of the distance difference in each second scatter region;
determining a similarity coefficient between the parameter matrix under test and the reference parameter matrix; and
determining the health score S of the alternating current motor under test based on a formula
$$S = \frac{{η}^{″} - 0.7}{( 1 - 0.7 ) * 0.01} ,$$
wherein η″ is the similarity coefficient.

14. The computer device according to claim 13, wherein the determining the similarity coefficient between the parameter matrix under test and the reference parameter matrix comprises:
determining a covariance between the parameter matrix under test and the reference parameter matrix;
determining a first standard deviation of the parameter matrix under test and a second standard deviation of the reference parameter matrix;
determining a product value of the first standard deviation and the second standard deviation; and
determining the similarity coefficient between the parameter matrix under test and the reference parameter matrix according to the covariance and the product value of the first standard deviation and the second standard deviation; the similarity coefficient is a quotient between the covariance and the product value.

15. The computer device according to claim 11, wherein the determining the kurtosis value of the distance difference, the skewness value of the distance difference, and the root mean square value of the distance difference in each first scatter region comprises:
determining the kurtosis value χ of the distance difference in each first scatter region according to the formula
$$χ = \frac{1}{N} {\sum }_{i = 1}^{N} {d}_{i}^{4} ;$$
determining the skewness value γ of the distance difference in each first scatter region according to the formula
$$γ = \frac{1}{N} {\sum }_{i = 1}^{N} {d}_{i}^{3} ;$$
determining the root mean square value Xᵣₘₛ of the distance difference in each first scatter region according to the formula
$${X}_{rms} = \sqrt{\frac{1}{N} {\sum }_{i = 1}^{N} {d}_{i}^{2}} ;$$
wherein
N is a number of distance differences in the first scatter region, i is a index of the distance difference in the first scatter region, dᵢ is the i-th distance difference.
